(19) United States
(12) Patent Application Publication
(10) Pub. No.: US 2017/0033957 A1
(43) Pub. Date: Feb. 2, 2017

(54) ADAPTIVE CABLE EQUALIZER FOR DIGITAL COMMUNICATION

(71) Applicant: Wanpeng Cao, Fremont, CA (US)

(72) Inventor: Wanpeng Cao, Fremont, CA (US)

(21) Appl. No.: 15/221,601

(22) Filed: Jul. 28, 2016

Related U.S. Application Data
(60) Provisional application No. 62/198,005, filed on Jul. 28, 2015.

(51) Int. Cl. H04L 27/01; H03H 11/06

(52) U.S. Cl. CPC H04L 27/01; H03H 11/06

(57) ABSTRACT

A single stage cable equalizer with a differential input stage, a source degeneration RC network and a folded cascode output stage achieves the inverse transfer function of a cable with a 1st order attenuation. The equalizer can be made adaptive by tuning the design parameters of the equalizer, such as source degeneration capacitor C in a feedback loop configuration. Multiple single stage equalizers can be cascoded to equalize the cable with a higher order attenuation.

### BACKGROUND

This application relates to the architecture and circuit implementation of adaptive cable equalizer in a digital data communication system.

When digital data stream is transmitted over a physical channel, such as coaxial cable, due to the cable's parasitic resistance, parasitic capacitance and parasitic inductance, the signal would be attenuated along the cable. Furthermore, the magnitude of the attenuation is frequency dependent, with higher attenuation for higher frequency band. On the receiver side, an equalizer is put in the front end to compensate for this cable attenuation to assure reliable data reception.

### SUMMARY

The proposed single stage adaptive cable equalizer has a 1st order transfer function in frequency domain. Depending on the cable type, cable length and transmitted digital signal bit rate, multiple equalizer stages may be put in series connection to achieve higher order equalization. The overall transfer function of the equalizer is adaptive by tuning the design parameters of the equalizer.

All patents, patent applications, articles, other publications, documents and things referenced herein are hereby incorporated by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWING

FIGS. 1-5 show various embodiments.

### DETAILED DESCRIPTION

FIG. 1 shows the block diagram of a receiver in a digital signal communication system. The digital data stream Vs enters a physical channel such as coaxial cable and reaches the receiver with an amplitude attenuated signal stream Vin. The transfer function from Vs to Vin in a 1st order system can be expressed as:

$$\frac{Vin}{Vs} = \frac{1}{1 + sA} \qquad EQ . 1$$

where s=2πfj, A is a cable dependent constant and f is the frequency. CDR is the clock data recovery system. In order to recover the transmitted digital data Vs reliably, an equalizer system EQ is put in front of CDR to compensate for the attenuation shown in EQ. 1, and the ideal transfer function of the equalizer would be the inverse of EQ. 1:

$$\frac{Vout}{Vin} = 1 + sA \qquad EQ . 2$$

and the overall transfer function from Vs to Vout would be 1, shown in EQ. 3.

$$\frac{Vout}{Vs} = \frac{Vin}{Vs} \frac{Vout}{Vin} = \frac{1}{1 + sA} ( 1 + sA ) = 1 \qquad EQ . 3$$

EQ's 1 to 3 are for 1st order system. Depending on the cable type, cable length and digital signal bit rate, higher order transfer function may be required to compensate the higher order attenuation of the cable. In those cases, multiple 1st order equalizer stages connected in series are needed. The design parameters of each of the equalizer stage could be different (such as parameter A in EQ. 2 to generate the overall inverse frequency transfer function of the cable.

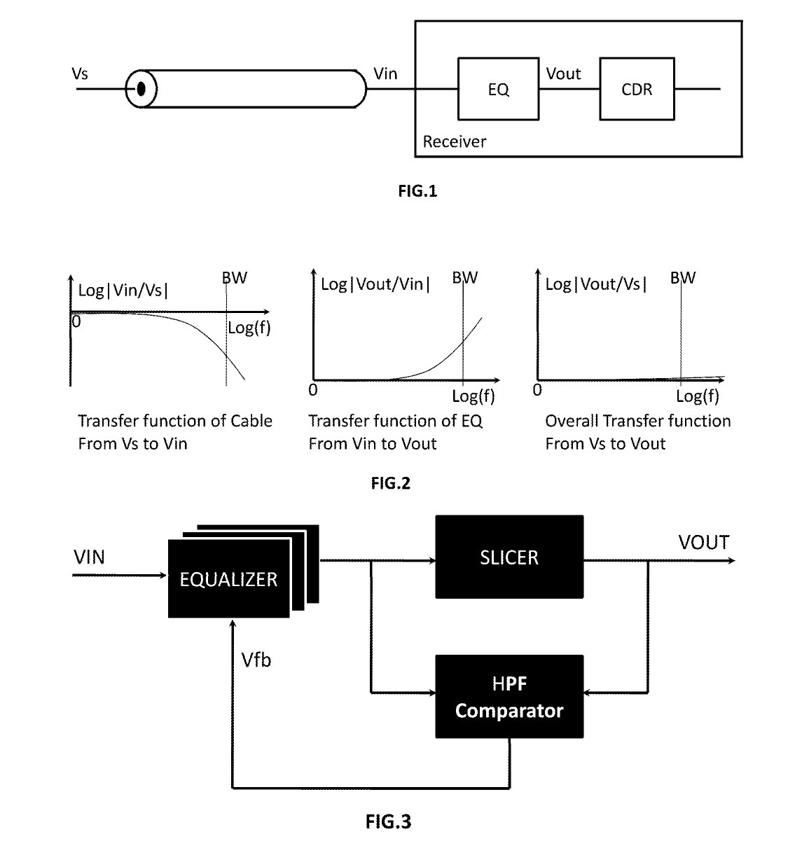

FIG. 2 shows the plots of EQ.1 to EQ.3 in LOG scale. X axis is the frequency f and y axis is the amplitude of the transfer function. BW is the optimal bandwidth the equalizer should work up to. BW is normally decided by the digital signal bit rate.

FIG. 3 illustrates a traditional functional block diagram of an adaptive equalizer system. The equalizer block contains one or more equalizer stages in series connection. SLICER is used to slice the recovered signal to generate the digital data stream. High pass filter (HPF) extracts the high frequency information. Comparator uses these high frequency information to generate the feedback control voltage Vfb. Vfb controls equalizer to make the overall system adaptive to different cable attenuations in a feedback configuration.

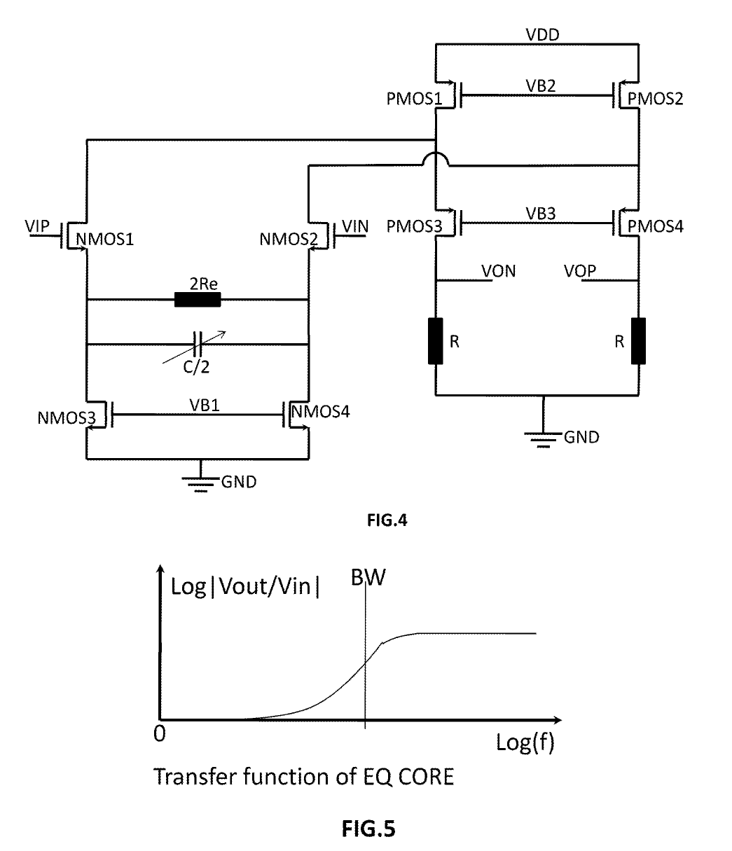

FIG. 4 shows the circuit implementation of the proposed equalizer. It is a full differential design with a differential input stage formed by NMOS transistors NMOS1 and NMOS2. The input stage bias is generated by NMOS3 and NMOS4 biased at a voltage of VB1 at the gates. The input stage has a source degeneration RC network consisting of resistor 2Re and capacitor C/2 in a parallel connection configuration. Feedback voltage Vfb is used to control and tune the value of the degeneration capacitor. PMOS transistors PMOS1, PMOS2, PMOS3 and PMOS4 form the folded cascode stage, where PMOS1 and PMOS2 biased at VB2 at the gates and PMOS3 and PMOS4 biased at VB3 at the gates. The folded cascode configuration is used to eliminated the miller effect of the equalizer frequency response and improve the bandwidth of the equalizer. The output load resistors are Ro's. The differential output of the equalizer is VOP and VON.

For the equalizer shown in FIG. 4, the differential output voltage Vout=VOP−VON and the differential input voltage is Vin=VIP−VIN. The transfer function of the equalizer can be expressed as:

$$\frac{Vout}{Vin} = \frac{GmRo ( sReC + 1 )}{( 1 + GmRe ) + sReC} \qquad EQ . 4$$

where:

Gm is the trans-conductance of input differential pair. We assume the output impendence of MOS transistors are much larger than Ro. In the design, GmRe is normally much larger than 1. At low to medium frequencies, |1+GmRe| is much larger than |sReC|, thus, EQ. 4 can be reduced to:

$$\frac{Vout}{Vin} = \frac{GmRo ( 1 + sReC )}{1 + GmRe} \qquad EQ . 5$$

Furthermore, if GmGe>>1 and Re=Ro, EQ. 5 can be reduced to:

$$\frac{Vout}{Vin} = 1 + sReC \qquad EQ . 6$$

which has a same form of EQ.2 with adaptive feedback control on to achieve ReC=A.

The transfer function of the equalizer

$$\frac{Vout}{Vin}$$

is plotted in FIG. 5 in LOG scale. To achieve a full bandwidth equalization up to the desired bandwidth, Gm/C should be set much higher than BW. The capacitor value is controlled by the feedback voltage Vfb to make system adaptive.

Applications

The hardware design described above can be applied for all digital data transmission systems with a physical transmission media, such as transmission lines, coaxial cable or CAT5 cable etc.

Conclusions

The foregoing detailed description is for illustration. The described embodiments are chosen in order to best explain the principles of the invention. It is not intended to be exhaustive or to limit the invention to the precise forms disclosed. Many variations are possible. It is intended that the scope of the invention be defined by the claims appended hereto.

1. An adaptive 1st order cable equalizer circuit implementation comprising: a differential input stage configured to receive the input signal; a folded cascode stage to reduce the miller effect of input stage to increase the bandwidth of equalizer; a source degeneration RC network to provide the desired equalization frequency response.

2. The equalizer circuit of claim 1 wherein the input differential pair is a transistor pair such as MOS transistor or BJT transistor.

3. The equalizer circuit of claim 1 wherein the folded cascode stage is formed by cascode MOS transistor or BJT transistor to improve the bandwidth of equalizer.

4. The equalizer circuit of claim 1 wherein the input degeneration RC network is formed by resistor and capacitor in parallel configuration.

5. The RC degeneration network of claim 4 wherein R and C are integrated on chip or connected outside off chip.

6. A method of adaptively adjusting the equalizer transfer function by tuning the design parameters of the equalizer circuit to match its transfer function to the inverse transfer function of the cable.

7. The method of claim 6 wherein the tunable parameters are input differential pair trans-conductance Gm, source degeneration resistor Re, source degeneration capacitor C and loading resistor Ro.

8. The method of claim 6 wherein cascading multiple 1st order equalizers to achieve a higher order overall transfer function to equalize the frequency response of the cables with higher order attenuations.
